(19) United States
(12) Patent Application Publication
(10) Pub. No.: US 2018/0165053 A1
(43) Pub. Date: Jun. 14, 2018

(54) DOCKING STATION WITH DUAL-DISPLAY SYNCHRONOUS OUTPUT

(71) Applicant: WIESON TECHNOLOGIES CO., LTD., New Taipei City (TW)

(72) Inventors: Tung-Hua KUO, New Taipei City (TW); Chia-Hung WANG, New Taipei City (TW)

(21) Appl. No.: 15/436,104

(22) Filed: Feb. 17, 2017

(30) Foreign Application Priority Data
Dec. 13, 2016 (TW) 105218991

(51) Int. Cl. G06F 3/14; H05K 5/00; H05K 5/02; H01R 24/60; H01R 27/02; H01R 31/00

(52) U.S. Cl. CPC G06F 3/1454; G06F 3/1423; H05K 5/0017; H05K 5/0247; H01R 2107/00; H01R 24/60; H05K 5/0065; H01R 27/02; H01R 31/005; H05K 5/0069

(57) ABSTRACT

A docking station includes electrical module that includes circuit board having conducting contacts and circuit layout arranged thereon, control system including a main control unit, an image signal processing unit for receiving a display port signal and converting it into an analog signal and a digital signal for synchronous output and a USB signal processing unit for converting a USB signal into multiple USB signals for output, a transmission cable assembly electrically connected to the control system for the connection of an external electronic apparatus, an image output interface including an analog signal output port and a digital signal output port for receiving analog and digital signals from the image signal processing unit for output to respective external display devices for display and a connector module for receiving the multiple USB signals from the USB signal processing unit for output to multiple external apparatuses for two-way power and data transmission.

This application claims the priority benefit of Taiwan patent application number 105218991, filed on Dec. 13, 2016.

### BACKGROUND OF THE INVENTION

### 1. Field of the Invention

The present invention relates to docking station technology and more particularly, to a docking station with dual-display synchronous output, which comprises a housing and an electrical module mounted in the housing, wherein the control system on the circuit board of the electrical module provides 4-channel signal and USB power delivery functions for enabling analog and digital signals to be synchronously transmitted to two display devices for display and USB signals to be transmitted to multiple external apparatuses for charging and data transmission.

### 2. Description of the Related Art

Nowadays, the rapid path of the growing of electronic technology makes the development of small and portable notebook computer to substitute for desktop computer, and thus, notebook computer has been widely used in every corner of the society. It is the market trend to create high computing power and high speed computers and energy-saving display screens capable of displaying delicate images. People either at home, personal studio, company or corporation will use a computer, laptop or other electronic device for connection to the Internet, playing multimedia, providing audio-visual entertainment services and/or performing word processing.

With the development of computer-related equipment on open architecture and the standardization of hardware and software, and with the continuous expansion and upgrading of functions, manufacturers have also developed various industrial computers for use in different fields to satisfy different high-performance requirements.

Further, in computers, laptops and industrial computers, in addition to the central processing unit (CPU) and memory of the motherboard that are used as the information processing hub, a variety of peripherals (such as screen, speaker, modem, printer, external hard drive, etc.) are also important for image display, data transmission and command control. The motherboard of a computer, laptop or other computer-related equipment generally provides various different slots for the installation of various different types interface cards for communication between various different peripheral devices and the host and for the purposes of data transmission and expansion of functions. However, due to the current requirements of electronic devices to exhibit the characteristics of small size, light weight and high mobility, there are limitations on component size and electronic device dimensions. Therefore, docking stations are created for allowing screens, computer peripherals, surround sound speakers, fiber optic network or other peripheral devices to be connected to a mobile computer to expand the function and to meet different management and control needs.

When an electronic device is to be connected to an external peripheral device through a docking station, a so-called peripheral interface device is needed. Universal Serial Bus (USB) is the most common connectivity solution for PCs and consumer devices today. For the advantage of supporting hot-swappable plug and play, the use of USB is more convenient. Nowadays, USB3.0 connectors have been widely used in all kinds of external peripherals. Facing the challenges of other high-speed interface devices, manufacturers have introduced USB3.1 Type-C interface specifications. A USB3.1 Type-C connector is relatively smaller than the existing connectors and capable of supporting higher power charging and power supply, and its transmission speed can be up to 10 Gbps. Further, a USB3.1 Type-C connector is double-sided pluggable and applicable to smart phones, tablet PCs and other light and small electronic devices. Therefore, USB3.1 Type-C is particularly expected by the market.

However, conventional docking stations are simply equipped with USB connectors, RJ45 connectors, High-Definition Multimedia Interface (HDMI) connectors, or Video-Image Array (VGA) connectors. Further, commercial notebook computers support VGA and HDMI connections, however, they do not allow connection of two display screens or projectors at the same time. When wishing to connect two display screens or projectors to a notebook computer, it is necessary to purchase an extra USB external display card device, causing considerable inconvenience in portability and increasing the cost. Further, when using a computer or notebook computer, its connector module does not allow connection of multiple external apparatuses (such as notebook computers, tablet computers, smart phones, etc.) for two-way charging and data transmission.

Therefore, it is desirable to provide a docking station, which solves the above-described problems.

### SUMMARY OF THE INVENTION

The present invention has been accomplished under the circumstances in view. It is therefore the main object of the present invention to provide a docking station, which comprises a housing and an electrical module mounted in the housing. The electrical module comprises a circuit board, a control system comprising a main control unit supporting USB Type-C interface specification, an image signal processing unit capable of converting a display port signal into an analog signal and a digital signal for synchronous output and a USB signal processing unit for converting a USB signal into multiple USB signals for output, a transmission cable assembly for the connection of an external electronic apparatus (such as computer, notebook or smart phone), an image output interface, and a connector module for receiving multiple USB signals for output to multiple external apparatuses for two-way power and data transmission. When the main control unit of the control system executes a USB Type-C mode control, the outputted display port (DP) signal of the electronic apparatus is transmitted through two channels (Tx0, Rx0) of the circuit layout to the image signal processing unit, and the converted by the image signal processing unit into an analog signal (such as VGA) and a digital signal (such as HDMI or DVI) for providing to two external display means (such as screens, projectors, etc.) synchronously. Further, USB signals (such as USB3.0 signal, USB3.1 signal are transmitted through the other two channels (Tx1, Rx1) to the USB signal processing unit for providing to multiple external apparatuses (such as notebook computers, tablet computers, smart phones, etc.) via the connector module for two-way charging and data transmission. Further, integrating the electrical module into one single circuit board can simplify the circuit layout design and modularization, saving much space occupation, and making the docking station more convenient for carrying and application to meet the needs of charging and display.

According to another aspect of the present invention, the image out interface comprises an analog signal output port and a digital signal output port and adapted for respectively receiving the outputted analog signal and digital signal from the image signal processing unit for output to multiple external display devices for display. Further, the connector module comprises a USB Type-C connector and a USB connector respectively electrically connected to the USB signal processing unit. The USB Type-C connector is electrically connected to the transmission cable assembly through the circuit layout to support USB power transmission, enabling the transmission cable assembly to provide power (for example, 60 W) and USB data transmission functions and enhancing docking station practicality and applicability.

According to still another aspect of the present invention, the control system of the electrical module further comprises a network signal converter electrically connected to the USB signal processing unit and adapted for converting a USB signal into a network signal (LAN signal, such as Gigabit Ethernet signal) for output to another external apparatus for data transmission. The connector module further comprises a network connector (such as RJ45 connector) electrically connected to the network signal converter and adapted for the connection of an external apparatus (such as broadband modem) for network signal transmission.

Other advantages and features of the present invention will be fully understood by reference to the following specification in conjunction with the accompanying drawings, in which like reference signs denote like components of structure.

### BRIEF DESCRIPTION OF THE DRAWINGS

FIG. 1 is an oblique top elevational view of a docking station in accordance with the present invention.

FIG. 2 is an exploded view of the docking station in accordance with the present invention.

FIG. 3 corresponds to FIG. 2 when viewed from another angle.

FIG. 4 is a circuit block diagram of the electrical module of the docking station in accordance with the present invention.

FIG. 5 is a schematic applied view of the docking station in accordance with the present invention (I).

FIG. 6 is a schematic applied view of the docking station in accordance with the present invention (II).

### DETAILED DESCRIPTION OF THE PREFERRED EMBODIMENT

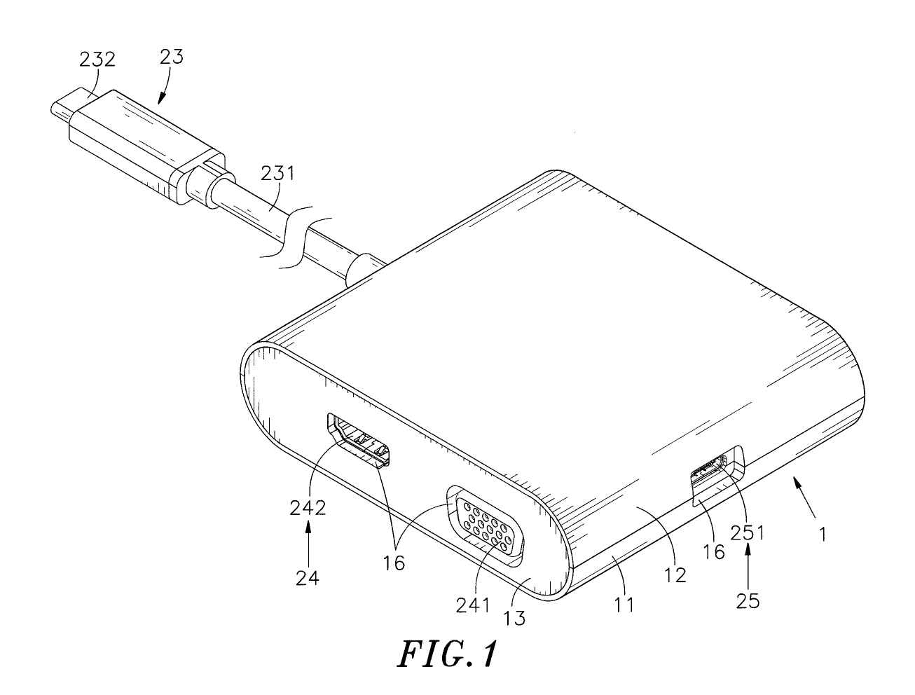

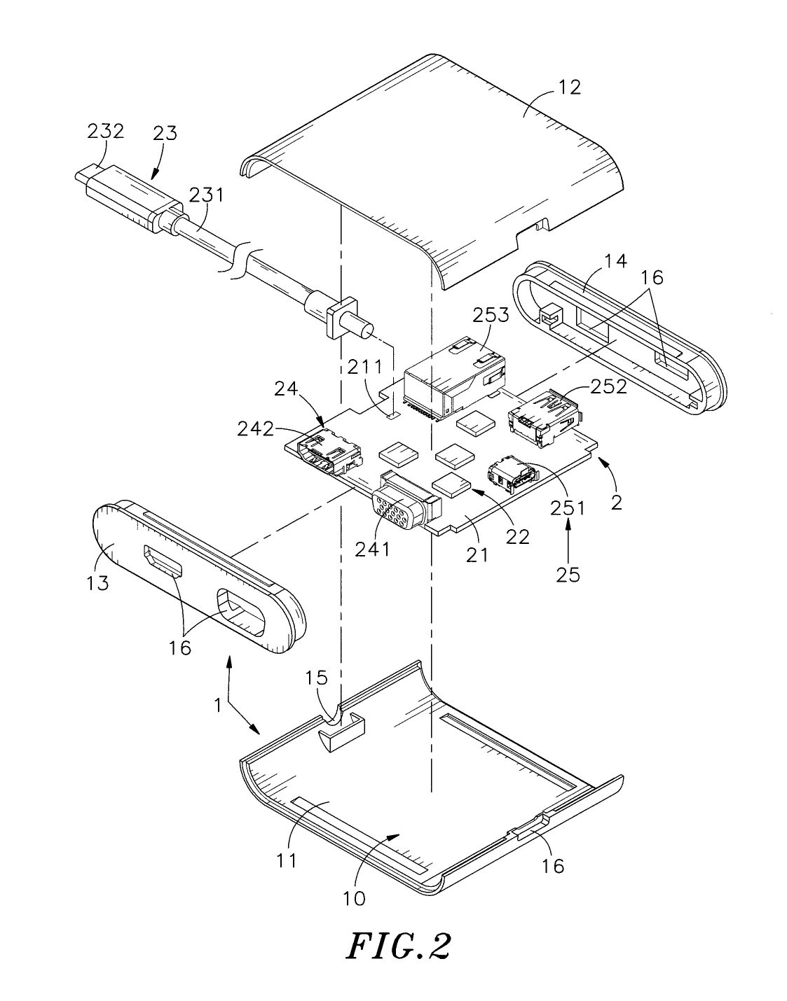

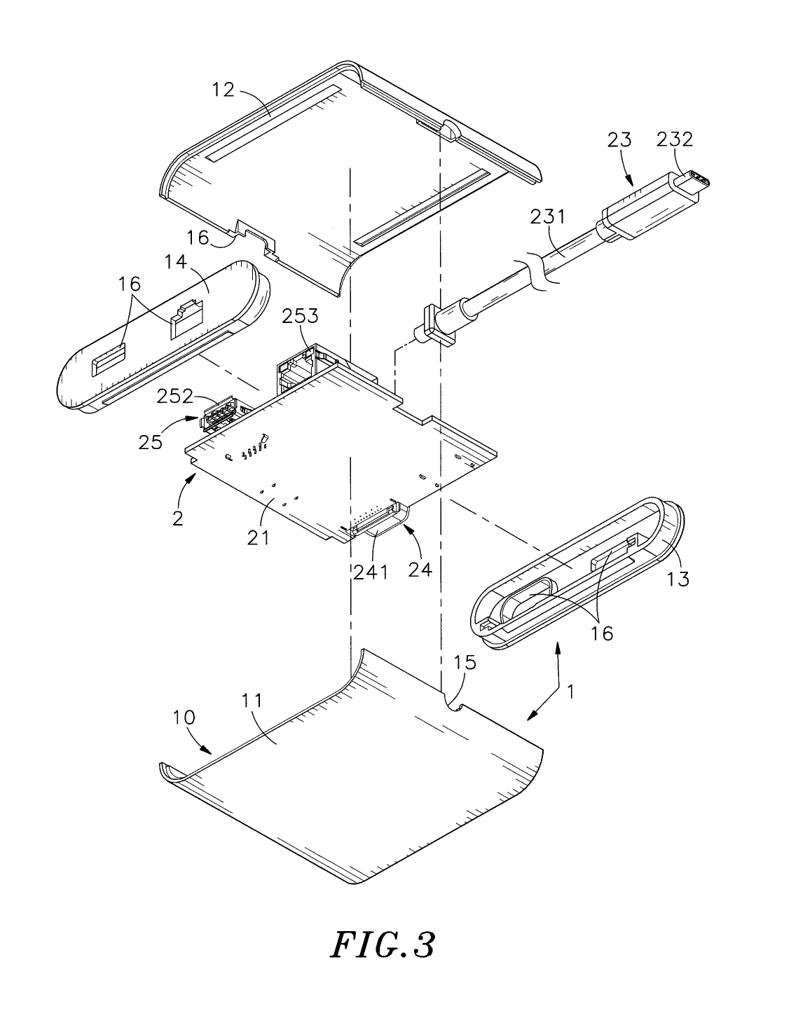

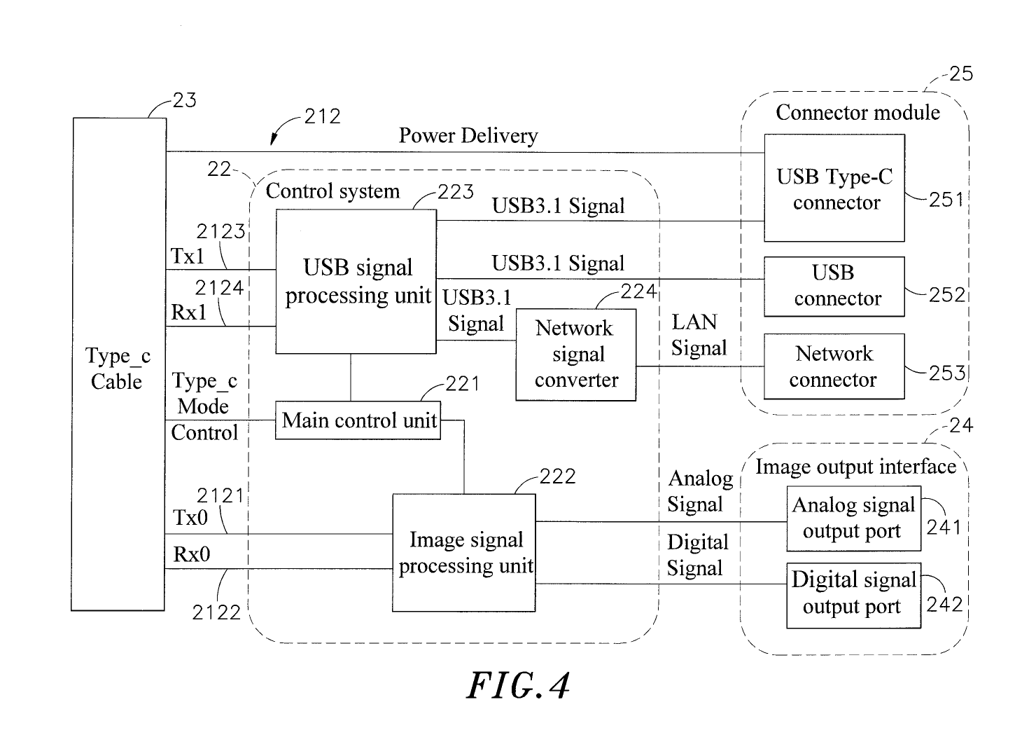

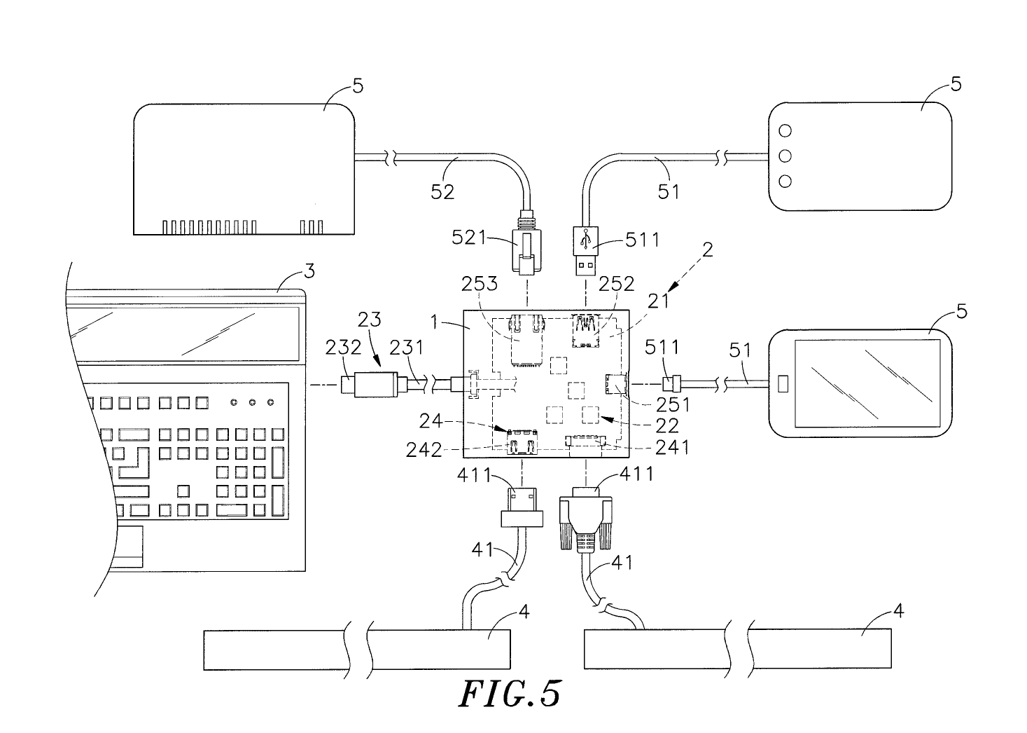

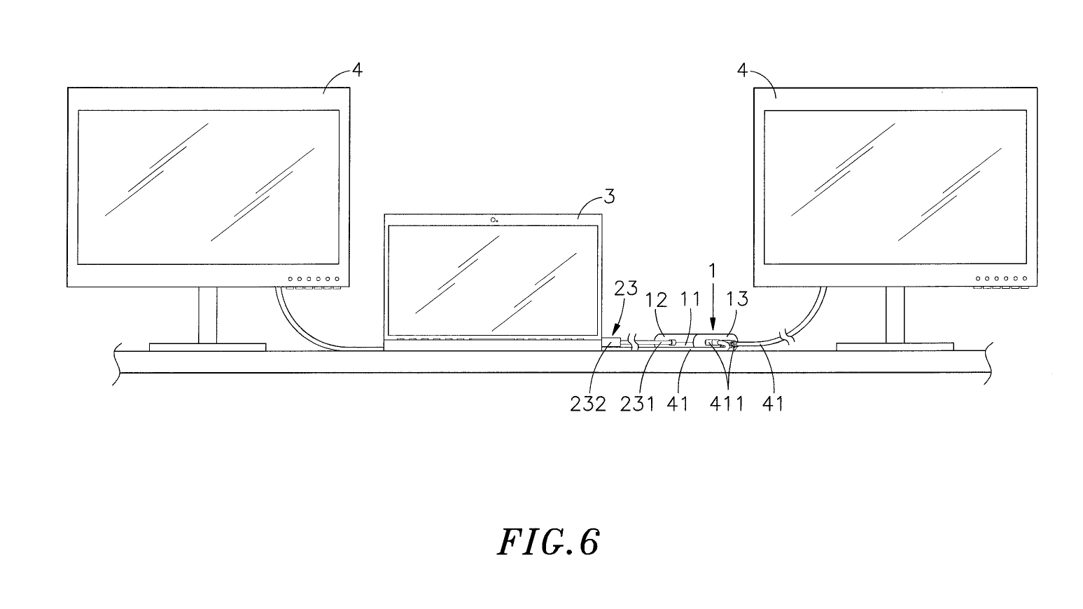

Referring to FIGS. 1-6, an oblique top elevational view of a docking station in accordance with the present invention, an exploded view of the docking station, another exploded view of the docking station, a circuit block diagram of the electrical module of the docking station, a schematic applied view of the docking station and another schematic applied view of the docking station are shown. As illustrated, the dock station comprises a housing 1 and an electrical module 2.

The housing 1 comprises a base panel 11, a top cover panel 12 covered on a top side of the base panel 11, a front panel 13 and back panel 14 respectively connected between the base panel 11 and the top cover panel 12 at opposite front and rear sides, an accommodation chamber 10 surrounded by the base panel 11, the top cover panel 12, the front panel 13 and the back panel 14 for accommodating the electrical module 2, and an insertion hole 15 and a plurality of slots 16 located on the base panel 11, the top cover panel 12, the front panel 13 and the back panel 14.

The electrical module 2 comprises a circuit board 21 with conducting contacts 211 and a circuit layout 212, a control system 22 installed in the circuit board 21, and a transmission cable assembly 23. The transmission cable assembly 23 comprises a cable 231 that is inserted through the insertion hole 15 of the housing 1 and electrically connected with one end thereof to the control system 22 through the circuit layout 212 and the conducting contacts 211, and a USB Type-C connector 232 located at an opposite end of the cable 231 and disposed outside the housing 1. The control system 22 comprises a main control unit 221 that supports USB Type-C (USB-C) interface specification, an image signal processing unit 222 electrically connected to the main control unit 221 and adapted for receiving a display port signal (DP signal) and converting it into an analog signal, such as video graphics array (VGA, standard D-sub connector) and a digital signal, such as high-definition multimedia interface (HDMI) signal or digital visual interface (DVI) signal for synchronous output, a USB signal processing unit 223 electrically connected to the main control unit 221 and adapted for converting a USB signal (such as USB3.0 signal) into many USB signals (such as USB3.0 signal, USB3.1 signal, etc.) for output, and a network signal converter 224 electrically connected to the USB signal processing unit 223 and adapted for converting a USB signal (for example, USB3.0 signal) into a network signal (LAN signal, such as Gigabit Ethernet signal) for output.

In the present preferred embodiment, the transmission cable assembly (Type-C Cable) 23 is electrically connected to the control system 22 through the circuit layout 212 and the conducting contacts 211 for Type-C Mode Control). The circuit layout 212 comprises a first channel 2121 (such as Tx0), a second channel 2122 (such as Rx0), a third channel 2123 (such as Tx1) and a fourth channel 2124 (such as Rx1). The transmission cable assembly 23 has the signal distribution of A1˜A12 (such as GND,TX1+,TX1−, Vbus, CC, D+, D−,SUB1, Vbus, RX2−,RX2+,GND) and B1˜B12 (such as GND,TX2+,TX2−, Vbus, VCONN, NC, NC, SBU2, Vbus,RX1+,RX1+,GND). The image signal processing unit 222 is electrically connected to TX1+,TX1−,RX1−,RX1+ of the cable 231 through the first channel 2121 (Tx0) and second channel 2122 (Rx0) of the circuit layout 212. The USB signal processing unit 223 is electrically connected to TX2+,TX2−, RX2−, RX2+ of the cable 231 through the third channel 2123 (Tx1) and fourth channel 2124 (Rx1) of the circuit layout 212. Thus, the transmission cable assembly 23 is capable of receiving image signals and USB signals.

The electrical module 2 further comprises an image output interface 24 electrically connected to the image signal processing unit 222 of the control system 22, and a connector module 25 electrically connected to the USB signal processing unit 223 of the control system 22. The image output interface 24 comprises an analog signal output port 241 (such as VGA connector) and a digital signal output port 242 (such as HDMI or DVI connector) respectively exposed to one respective slot 16 of the housing 1. The connector module 25 comprises a USB Type-C connector 251 and a USB connector 252 (such as USB3.0, Mini USB or Micro-USB connector) respectively electrically connected to the USB signal processing unit 223 and respectively exposed to one respective slot 16 of the housing 1, and a network connector 253 (such as RJ45 connector) electrically connected to the network signal converter 224 of the control system 22 and exposed to one respective slot 16 of the housing 1. Further, the USB Type-C connector 251 also electrically connected to the cable 231 of the transmission cable assembly 23 through the circuit layout 212 to support USB Power Delivery specification, allowing the transmission cable assembly 23 to provide power (such as 60 W) and data transmission functions.

When using an electronic apparatus 3 (such as computer, notebook computer or smart phone) with the docking station of the present invention, connect the USB Type-C connector 232 of the transmission cable assembly 23 of the electrical module 2 to a mating USB-C (female) connector of the electronic apparatus 3, enabling the electronic apparatus 3 to provide four-channel (Tx0,Rx0,Tx1,Rx1) signals to the control system 22 through the transmission cable assembly 23 and the circuit layout 212 of the circuit board 21 and also to provide 6 oW power and data transmission through the USB power delivery (PD). Thereafter, connect respective connection ports 411 of respective video transmission cables 41 of two display devices 4 (such as display screens, projectors, etc.) to the analog signal output port 241 and digital signal output port 242 of the image output interface 24. When the main control unit 221 of the control system 22 executes a USB Type-C mode control according to the program instructions, the outputted display port (DP) signal of the electronic apparatus 3 is transmitted through the first channel 2121 (Tx0) and second channel 2122 (Rx0) of the circuit layout 212 to the image signal processing unit 222, and the converted by the image signal processing unit 222 into an analog signal (such as VGA) and a digital signal (such as HDMI or DVI), and then synchronously transmitted through the analog signal output port 241 and digital signal output port 242 of the image output interface 24 and the respective video transmission cables 41 to the two display devices 4 for display. Further, the display device 4 can be changed to a synchronous or extended display mode according to the setting of the electronic apparatus 3. Further, integrating the electrical module 2 into one single circuit board 21 can simplify the circuit layout design and modularization, saving much space occupation, and making the docking station more convenient for carrying and application to meet the needs of charging and display.

Further, in the application of the docking station, the user can connect the matting USB connectors 511 of the USB transmission cables 51 of multiple external apparatuses 5 (such as notebook computer, tablet computer, smart phone, etc.) to the USB Type-C connector 251 and USB connector 252 of the connector module 25, and then connect the RJ45 connector 521 of the network transmission cable assembly 52 of another external apparatus 5 (such as broadband modem, set-top box, multimedia service platform, etc.) to the network connector 253 of the connector module 25. Thus, when the main control unit 221 of the control system 22 executes a USB Type-C mode control, the electronic apparatus 3 can transmit power supply through the USB power delivery (PD) of the circuit layout 212 to the USB Type-C connector 251 of the connector module 25 and a USB signal through the third channel 2123 (Tx1) and fourth channel 2124 (Rx1) of the circuit layout 212 to the USB signal processing unit 223, allowing the USB signal processing unit 223 to convert the received USB signal (such as USB3.0 Signal) into many USB signals (such as USB3.0 signal, USB3.1 signal, etc.) for transmission to the USB Type-C connector 251, the USB connector 252 and the network signal converter 224, where the network signal converter 224 converts the USB signal into a network signal (such as LAN Signal) that is then transmitted to the network connector 253. Thus, through the connector module 25, the docking station can communicate with multiple external apparatuses 5 to perform two-way charging and data transmission function, improving practicality and applicability.

In conclusion, the invention provides a docking station, which comprises a housing 1, and an electrical module 2 mounted in the housing 1, wherein the electrical module 2 comprises a circuit board 21 having a circuit layout 212 and conducting contacts 211 arranged thereon, a control system 22 consisting of a main control unit 221, an image signal processing unit 222 and a USB signal processing unit 223 and installed in the circuit board 21, a USB-C transmission cable assembly 23 with the cable 231 thereof electrically connected to the control system 22 through the circuit layout 212 and the conducting contacts 211 and the USB Type-C connector 232 thereof disposed outside the housing 1, an image output interface 24 electrically connected to the control system 22, and a connector module 25 electrically connected to the control system 22. When the main control unit 221 executes USB Type-C mode control and provides signals and USB power delivery (PD) to the four channels (such as Tx0,Rx0,Tx1,Rx1) of the circuit layout 212, a display port (DP) signal can be transmitted through two channels (such as Tx0,Rx0) to the image signal processing unit 222 and the converted by the image signal processing unit 222 into an analog signal (such as VGA) and a digital signal (such as HDMI or DVI) for synchronous output to two display devices 4 for display, and a USB signal can be transmitted through the other two channels (such as Tx1,Rx1) to the USB signal processing unit 223 and then converted by the USB signal processing unit 223 into many USB signals for output to multiple external apparatuses 5 through the connector module 25 for two-way power and data transmission.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A docking station, comprising a housing and an electrical module mounted in said housing, wherein:
said electrical module comprises:
a circuit board having conducting contacts and a circuit layout arranged thereon;
a control system installed in said circuit board, said control system comprising a main control unit supporting USB Type-C interface specification, an image signal processing unit electrically connected to said main control unit and adapted for receiving a display port signal and converting said display port signal into an analog signal and a digital signal for synchronous output and a USB signal processing unit electrically connected to said main control unit and adapted for converting a USB signal into multiple USB signals for output;
a transmission cable assembly electrically connected to said control system through said circuit layout and said conducting contacts and extended out of said housing for the connection of an external electronic apparatus;
an image output interface electrically connected to said image signal processing unit, said image output interface comprising an analog signal output port and a digital signal output port and adapted for respectively receiving the outputted said analog signal and said digital signal from said image signal processing unit for output to a respective external display device for display; and
a connector module electrically connected to said USB signal processing unit and adapted for receiving the said multiple USB signals for output to multiple external apparatuses for two-way power and data transmission.

2. The docking station as claimed in claim 1, wherein said housing comprises an insertion hole for the passing of said transmission cable assembly and a plurality of slots for allowing said analog signal output port and said digital signal output port of said image output interface and said connector module to be exposed to the outside of said housing.

3. The docking station as claimed in claim 2, wherein said housing comprises a base panel, a top cover panel covered on a top side of said base panel, a front panel and back panel respectively connected between said base panel and said top cover panel at opposite front and rear sides, and an accommodation chamber surrounded by said base panel, said top cover panel, said front panel and said back panel for accommodating said electrical module.

4. The docking station as claimed in claim 1, wherein said transmission cable assembly comprises a cable inserted through said housing and electrically connected with one end thereof to said control system through said circuit layout and said conducting contacts, and a USB Type-C connector located at an opposite end of said cable and disposed outside said housing.

5. The docking station as claimed in claim 1, wherein said circuit layout of said circuit board of said electrical module comprises a first channel, a second channel, a third channel and a fourth channel; said image signal processing unit of said control system is electrically connected with said transmission cable assembly through said first channel and said second channel of said circuit layout; said USB signal processing unit is electrically connected with said transmission cable assembly through said third channel and said fourth channel of said circuit layout.

6. The docking station as claimed in claim 1, wherein said connector module of said control system of said electrical module comprises a USB Type-C connector and a USB connector respectively electrically connected to said USB signal processing unit, said USB Type-C connector being electrically connected to said transmission cable assembly through said circuit layout for enabling said transmission cable assembly to provide power and USB data transmission functions.

7. The docking station as claimed in claim 1, wherein said control system of said electrical module further comprises a network signal converter electrically connected to said USB signal processing unit and adapted for converting a USB signal into a network signal for output; said connector module further comprises a network connector electrically connected to said network signal converter and adapted for the connection of an external apparatus for network signal transmission.

8. The docking station as claimed in claim 1, wherein said analog signal output port of said image output interface of said electrical module is a VGA connector; said digital signal output port of said image output interface of said electrical module is a HDMI or DVI connector.
